(19) United States
(12) Patent Application Publication
(10) Pub. No.: US 2026/0334271 A1
(43) Pub. Date: Oct. 22, 2026

(54) BONDING APPARATUS HAVING SYSTEM-ERROR COMPENSATION FUNCTION, AND METHOD

(71) Applicant: WUHAN XINXIN SEMICONDUCTOR MANUFACTURING CO., LTD., WUHAN (CN)

(72) Inventors: CHAO TAO, WUHAN (CN); JUNZHOU LONG, WUHAN (CN); LI WANG, WUHAN (CN)

(21) Appl. No.: 19/697,610

(22) Filed: Jun. 4, 2026

Related U.S. Application Data
(63) Continuation of application No. PCT/CN2023/138938, filed on Dec. 14, 2023.

(30) Foreign Application Priority Data
Dec. 7, 2023 (CN) 202311689978.9

(51) Int. Cl. H10W 72/00

(52) U.S. Cl. CPC H10W 72/07178; H10W 72/07113; H10W 72/07173; H10W 72/07183

(57) ABSTRACT

A bonding apparatus having a system-error compensation function is provided. The device includes: a movable object pick-up stage, configured to move a first element; a carrier stage, configured to move a second element; a first image-acquisition device, configured to read alignment marks of the first element and the second element driven to an alignment position; and a second image-acquisition device, configured to, in response to the bonding apparatus performing a system-error correction operation, read alignment marks of the first element and the second element driven to a bonding position, for obtaining a system-error compensation value. In response to the bonding apparatus performing a bonding operation, the bonding apparatus performs a system-error compensation operation based on the system-error compensation value, so that the first element and the second element driven to the bonding position are aligned.

### CROSS REFERENCE TO RELATED APPLICATIONS

This application is a continuation of International Patent Application No. PCT/CN2023/138938, filed on Dec. 14, 2023, which claims priority to China Patent Applicant No. 202311689978.9, filed on Dec. 7, 2023 in the China National Intellectual Property Administration, the entire contents of which are incorporated herein by reference.

### TECHNICAL FIELD

Embodiments of the present disclosure relate to the technical field of semiconductor manufacturing, in particular, to a bonding apparatus having a system-error compensation function and a method.

### BACKGROUND

As semiconductor technology enters the post-Moore era, in order to meet the demands for high integration density and high performance, chip structures are developing towards three-dimensional directions. Manufacturing stacked chips through bonding technology is one of the important technologies of the “More than Moore” approach. Bonding accuracy is an important parameter of the bonding process and has a great impact on the application of bonding technology.

### SUMMARY

According to some embodiments of the present disclosure, a bonding apparatus having a system-error compensation function and a related method are provided.

In a first aspect, some embodiments of the present disclosure provide a bonding apparatus having a system-error compensation function. The bonding apparatus may include a movable pick-up stage, a carrier stage, a first image-acquisition device, and a second image-acquisition device. The movable pick-up stage may be configured to move a first element. The carrier stage may be configured to move a second element. The first image-acquisition device may be configured to read alignment marks of both the first element and the second element that are driven to an alignment position. The second image-acquisition device may be configured to, in response to the bonding apparatus performing a system-error correction operation, read alignment marks of both the first element and the second element that are driven to a bonding position, for obtaining a system-error compensation value. The bonding apparatus may be configured to, in response to the bonding apparatus performing a bonding operation, perform a system-error compensation operation based on the system-error compensation value, for enabling the first element and the second element that are driven to the bonding position to be aligned to each other.

In a second aspect, some embodiments of the present disclosure provide a bonding method applied to a bonding apparatus. The method may include: moving, through at least one of a movable pick-up stage or a carrier stage of the bonding apparatus, a first element and a second element to an alignment position, respectively; reading, through a first image-acquisition device of the bonding apparatus, alignment marks of both the first element and the second element that are at the alignment position, for aligning the first element and the second element in a height direction; in response to the bonding apparatus performing a system-error correction operation, driving the first element and the second element to a bonding position, and identifying, through a second image-acquisition device of the bonding apparatus, alignment marks of both the first element and the second element at the bonding position, for obtaining a system-error compensation value of the bonding apparatus; and in response to the bonding apparatus performing a bonding operation, performing a system-error compensation operation based on the system-error compensation value, for enabling the first element and the second element that are driven to the bonding position to be aligned to each other.

The details of one or more embodiments of the present disclosure are set forth in the following drawings and description. Other features, objects, and technical effects of the present disclosure will become apparent from the description, the drawings, and the claims.

### BRIEF DESCRIPTION OF THE DRAWINGS

In order to more clearly illustrate the technical solutions in the embodiments of the present disclosure, the drawings that are required for the description of the embodiments will be briefly introduced below. Apparently, the drawings in the following description are merely some embodiments of the present disclosure. For those skilled in the art, other drawings may be obtained from these drawings without creative efforts.

FIG. 1 is a schematic structural view of a bonding apparatus according to some embodiments of the present disclosure.

FIG. 2 is a top view of a first image-acquisition device according to some embodiments of the present disclosure.

FIG. 3 is a top view of a second image-acquisition device according to some embodiments of the present disclosure.

FIG. 4 is a schematic state view of an alignment position according to some embodiments of the present disclosure.

FIG. 5 is a schematic state view of a non-alignment position according to some embodiments of the present disclosure.

FIG. 6 is a flowchart of a bonding method according to some embodiments of the present disclosure.

### DETAILED DESCRIPTION

The technical solutions in the embodiments of the present disclosure may be clearly and completely described below with reference to the accompanying drawings in the embodiments of the present disclosure. Apparently, the described embodiments may be only a part of the embodiments of the present disclosure, rather than all of the embodiments. Based on the embodiments of the present disclosure, all other embodiments obtained by those skilled in the art without making creative efforts may fall within the protection scope of the present disclosure.

The terms “first”, “second”, and “third” in the present disclosure may be used for descriptive purposes only, and may not be construed as indicating or implying relative importance or implicitly indicating the number of the indicated technical features. Thus, features defined with “first”, “second”, and “third” may explicitly or implicitly include at least one such feature. In the description of the present disclosure, “a plurality of” or “multiple” may mean at least two, for example, two, three, etc., unless otherwise specifically defined. All directional indications (such as up, down, left, right, front, back, etc.) in the embodiments of the present disclosure may be used only to explain the relative positional relationship, movement conditions, etc. among components under a specific posture (as shown in the drawings). If the specific posture changes, the directional indications may change accordingly. In addition, the terms “include”, “comprise”, and “have”, as well as any variations thereof, may be intended to cover non-exclusive inclusion. For example, a process, method, system, product, or device including a series of operations or units may not be limited to the listed operations or units, but may optionally include operations or units not listed, or may optionally include other operations or units inherent to such process, method, product, or device.

As used herein, references to “embodiment” may mean that a particular feature, structure, or characteristic described in connection with the embodiment may be included in at least one embodiment of the present disclosure. The appearances of this phrase in various places in the specification may not necessarily refer to the same embodiment, nor may they be independent or alternative embodiments mutually exclusive with other embodiments. It may be explicitly and implicitly understood by those skilled in the art that the embodiments described herein may be combined with other embodiments.

Furthermore, it is to be understood that the use of the term “substantially” herein, unless otherwise defined with respect to a specific context, with respect to a numeric quantity or otherwise quantifiable relationship, e.g., perpendicularity or parallelism, is to be understood as indicating that quantity +−10%. Thus, for example, lines that are substantially perpendicular to one another may be at angles between 81° and 99° to one another. In a further example, dimensions that are substantially between 1 mm and 3 mm, for example, may range from 0.9 mm to 3.3 mm. In another example, an angle that is substantially in the range of 1 to 1.1 radians may be between 0.9 radians and 1.21 radians.

The present disclosure may be described in detail below with reference to the accompanying drawings and embodiments.

As shown in FIG. 1, FIG. 1 is a schematic structural view of a bonding apparatus according to some embodiments of the present disclosure. In some embodiments, the bonding apparatus 100 may include: a movable pick-up stage 10, a carrier stage 20, a first image-acquisition device 30, and a second image-acquisition device 40.

The movable pick-up stage 10 may be configured to move or drive a first element 11. The carrier stage 20 may be configured to move or drive or carry a second element 21.

The first image-acquisition device 30 may be configured to read alignment marks of both the first element 11 and the second element 21 that are driven to an alignment position. The alignment position may refer to a state in which the alignment marks of both the first element 11 and the second element 21 appear within a field of view of the first image-acquisition device 30. In some embodiments, the bonding apparatus 100 may be further configured to adjust the first element 11 and the second element 21 at the alignment position based on the alignment marks read by the first image-acquisition device 30, such that the first element 11 and the second element 21 at the alignment position may be aligned in a height direction. For example, the bonding apparatus 100 may be configured to drive the movable pick-up stage 10 and/or the carrier stage 20 to perform adjustment based on information of the alignment marks read by the first image-acquisition device 30, so as to align the first element 11 and the second element 21. That is, in a case where the first element 11 and the second element 21 are located at a bonding initial position, an alignment mark of the first element 11 and an alignment mark of the second element 21 may be aligned in the height direction. The second image-acquisition device 40, in response to the bonding apparatus 100 performing a system-error correction operation, may be configured to read alignment marks of both the first element 11 and the second element 21 that are driven to a bonding position, for obtaining a system-error compensation value. The bonding position may refer to a region where the first element 11 and the second element 21 perform a bonding operation. For example, the movable pick-up stage 10 may be configured to move the first element 11, and/or the carrier stage 20 may be configured to move the second element 21, along the height direction to the bonding position where the first element 11 and the second element 21 complete bonding. The second image-acquisition device 40 may be configured to identify the alignment marks of both the first element 11 and the second element 21 that are driven to the bonding position, thereby obtaining the system-error compensation value.

Further, in response to the bonding apparatus 100 performing the bonding operation, the bonding apparatus 100 may be configured to perform a system-error compensation operation based on the system-error compensation value, such that the first element 11 and the second element 21 that are driven to the bonding position may be aligned to each other. For example, the bonding apparatus 100 may be configured to adjust the movable pick-up stage 10 and/or the carrier stage 20 based on the system-error compensation value, enabling the first element 11 and the second element 21 that move along the height direction and complete bonding may be aligned to each other.

The system-error compensation value may be a calibration compensation value, i.e., a compensation value for an alignment deviation caused by vertical displacement during a process in which the bonding apparatus 100 moves the first element 11 through the movable pick-up stage 10 and/or moves the second element 21 through the carrier stage 20, along the height direction to enable the first element 11 and the second element 21 to complete bonding. In some embodiments, the system-error compensation value may further include a compensation value for an alignment deviation caused by a bonding force applied to both the first element and the second element during the bonding process. Accordingly, performing the bonding operation based on the system-error compensation value may improve positioning accuracy and bonding efficiency of the bonding apparatus.

In some embodiments, in response to the bonding apparatus 100 performing the bonding operation, the bonding apparatus 100 may be configured to adjust the movable pick-up stage 10 and/or the carrier stage 20 based on the system-error compensation value. In this way, a system-error compensation operation may be performed on the first element 11 and the second element 21 that are at the alignment position. Then, the movable pick-up stage 10 and/or the carrier stage 20 may be moved along the height direction, for enabling the first element 11 and the second element 21 to be driven to the bonding position. In some embodiments, in response to the bonding apparatus 100 performing the bonding operation, the bonding apparatus 100 may be configured to move the movable pick-up stage 10 and/or the carrier stage 20 along the height direction to drive the first element 11 and the second element 21 to the bonding position. Meanwhile, the bonding apparatus 100 may be further configured to adjust the movable pick-up stage 10 and/or the carrier stage 20 based on the system-error compensation value to perform the system-error compensation operation on the first element 11 and the second element 21.

Further, the bonding apparatus 100 may further include a base 51 and a machine frame 52. In some embodiments, the movable pick-up stage 10 may be capable of moving along an X direction and a Y direction on a horizontal plane. The movable pick-up stage 10 may be further capable of moving along a height direction Z. The carrier stage 20 may be capable of moving along the X direction and the Y direction on the horizontal plane. The carrier stage 20 may further be capable of rotating on a vertical plane substantially perpendicular to the horizontal plane to adjust a horizontal state of the carrier stage 20, where a rotation angle θ may be a horizontal adjustment angle of the carrier stage 20.

It should be noted that FIG. 1 may only show embodiments in which the movable pick-up stage 10 is disposed at a top of the machine frame 52 and the carrier stage 20 is disposed on the base 51. In some other embodiments, the movable pick-up stage 10 may be disposed on the base 51, and the carrier stage 20 may be disposed at the top of the machine frame 52, as long as the first element 11 and the second element 21 may be moved to the bonding position. Thus, positions of the movable pick-up stage 10 and the carrier stage 20 may not be limited in the present disclosure.

In some embodiments, the base 51 and the machine frame 52 may jointly form or define a machine structure 50 having a cavity. The machine frame 52 may include a top plate 521 and a plurality of side plates 522 connected to the top plate 521, respectively. The base 51 may be substantially planar, and end portions of the plurality of side plates 522 of the machine frame 52 may be respectively disposed on the base 51. A machine structure 50 may further include a displacement acquisition member 53. The displacement acquisition member 53 may be a component, such as a laser interferometer, a planar grating, etc., that is capable of achieving high-precision positioning. Further, the displacement acquisition member 53 may be configured to determine displacement information of both the carrier stage 20 and the movable pick-up stage 10 along a first direction Y and a second direction X. Based on the displacement information along the first direction Y and the second direction X, the displacement acquisition member 53 may further be configured to determine coordinate information of both the second element 21 and the first element 11 in the first direction Y, and to determine coordinate information of both the second element 21 and the first element 11 in the second direction X.

In some embodiments, the movable pick-up stage 10 may be a macro-micro dual-stage motion mechanism. The macro-micro dual-stage motion mechanism may include a macro driving member capable of submicron-level coarse positioning and a micro driving member capable of submicron-level precision positioning. In this way, the movable pick-up stage may be configured to move in the X direction, the Y direction, the Z direction, and a rotational direction in a manner of “coarse adjustment +fine adjustment”. In some embodiments, the movable pick-up stage 10 may be formed by stacking a first driving member 111, a second driving member 112, a rotation driving member 113, and a bonding pick-up head 114, so as to pick up and move the first element 11. The bonding pick-up head 114 may be connected to the rotation driving member 113. An end of the bonding pick-up head 114 may face toward the first element 11. The first driving member 111 may be configured to move the second driving member 112 and the rotation driving member 113 along the first direction Y and/or the second direction X on the horizontal plane, thereby moving the bonding pick-up head 114 along the first direction Y and/or the second direction X on the horizontal plane. Further, the second driving member 112 may be configured to move the rotation driving member 113 along the third direction Z on a plane substantially perpendicular to the horizontal plane, thereby moving the bonding pick-up head 114 along the third direction Z. The rotation driving member 113 may be configured to rotate the bonding pick-up head 114. In this way, the bonding pick-up head 114 may be enabled to pick up the first element 11 and to drive the first element 11 to move along the height direction to complete bonding with the second element 21.

Correspondingly, the second driving member 112 may be configured to move the rotation driving member 113 along the third direction Z, thereby achieving precision positioning of the bonding pick-up head 114 along the third direction Z. The rotation driving member 113 may achieve micro-radian-level positioning accuracy.

It should be noted that the first driving member 111/the second driving member 112/the rotation driving member 113 may further include a motor, for example, a linear motor or a rotary motor, so as to provide power for the corresponding driving member. It may be understood that the structural design of the macro-micro dual-stage motion mechanism of the first driving member 111 in some embodiments of the present disclosure may further refer to a structure in the related art, as long as the bonding pick-up head 114 may be moved along the first direction Y on the horizontal plane and submicron-level positioning accuracy may be achieved, which is not limited herein. Correspondingly, the structural design of the macro-micro dual-stage motion mechanism of the second driving member 112 and the structural design of the macro-micro dual-stage motion mechanism of the rotation driving member 113 may further refer to structures in the related art, as long as their corresponding functions may be achieved.

The first direction Y, the second direction X, and the third direction Z may intersect with each other in pairs to establish a spatial coordinate system. In some embodiments, the first direction Y, the second direction X, and the third direction Z may be substantially perpendicular to each other in pairs, as shown in FIG. 1. In some embodiments, a direction in which a Y-axis lies may be substantially parallel to the first direction Y, a direction in which an X-axis lies may be substantially parallel to the second direction X, and a direction in which a Z-axis lies may be substantially parallel to the third direction Z. In this case, the first driving member 111 may further be referred to as a Y-axis or X-axis driving member, and the second driving member 112 may further be referred to as a Z-axis driving member.

In some embodiments, the movable pick-up stage 10 may further be a single-stage motion mechanism or other types of motion mechanisms, as long as the first element 11 to be bonded may be moved to a predetermined surface position of the second element 21 to be bonded under a condition of meeting a precision requirement, a high-precision displacement operation may be performed on the first element 11 based on the system-error compensation value, and the first element 11 may be bonded at the predetermined surface position of the second element 21 to be bonded.

In some embodiments, the carrier stage 20 may include a chuck 211 and a third driving member 212. The chuck 211 may be configured to carry the second element 21 to be bonded. The carrier stage 20 may include a macro-micro dual-stage motion mechanism. The third driving member 212 may be configured to move the chuck 211 along the first direction Y and/or the second direction X on a horizontal plane. The third driving member 212 may further be configured to rotate on a vertical plane substantially perpendicular to the horizontal plane to adjust a horizontal state of the carrier stage 20, where a rotation angle θ may be a horizontal adjustment angle of the carrier stage 20.

It may be understood that, the movable pick-up stage 10/the carrier stage 20 may be controlled by a plurality of driving devices moving in a horizontal direction, a height direction, and a rotational direction. In some embodiments, the movable pick-up stage 10 and/or the carrier stage 20 may be controlled by a single driving device capable of multiple positional and angular adjustments.

The third driving member 212 may include: a first direction driving member, a second direction driving member, and a horizontal adjustment member. The first direction driving member may be configured to move the chuck 211 along the first direction Y on the horizontal plane. The second direction driving member may be configured to move the chuck 211 along the second direction X on the horizontal plane. The horizontal adjustment member may be configured to rotate on a vertical plane substantially perpendicular to the horizontal plane to adjust the horizontal state of the carrier stage 20, where the rotation angle θ may be the horizontal adjustment angle of the carrier stage 20.

In some embodiments, the first image-acquisition device 30 may be configured to obtain the alignment mark of the first element 11 and the alignment mark of the second element 21. For example, the first image-acquisition device 30 may include an upward-looking image acquisition unit and a downward-looking image acquisition unit. The upward-looking image acquisition unit may have a first viewing angle and may be configured to identify the alignment mark of the first element 11. The downward-looking image acquisition unit may have a second viewing angle and may be configured to identify the alignment mark of the second element 21. The upward-looking image acquisition unit and the downward-looking image acquisition unit may be arranged opposite to each other. For example, when identifying the alignment marks, the upward-looking image acquisition unit may be located on a side of the base 51 facing the top plate 521 of the machine frame 52, and the downward-looking image acquisition unit may be located on a side of the top plate 521 of the machine frame 52 facing the base 51. In some embodiments, the upward-looking image acquisition unit and the downward-looking image acquisition unit may be arranged as an integral device, for example, an upper-and-downward looking image acquisition device. In this case, when identifying the alignment marks, the upper-and-downward looking image acquisition device may be located in a cavity formed jointly by the base 51 and the machine frame 52.

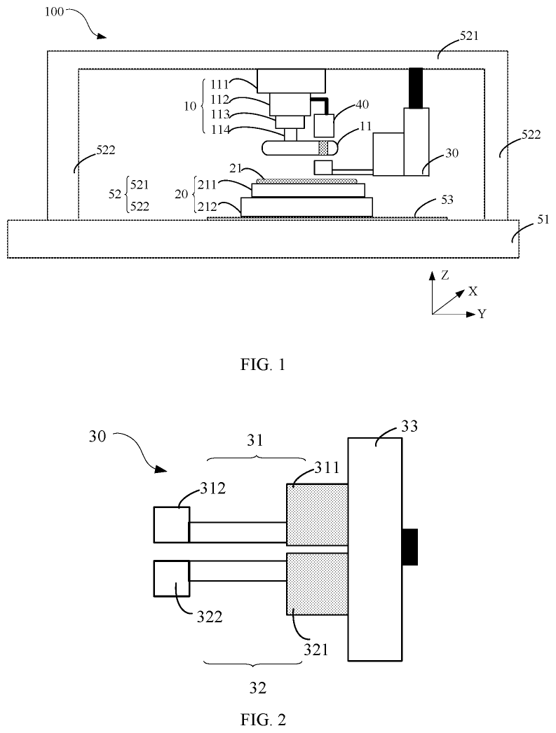

In some embodiments, the first image-acquisition device 30 may be exemplified as an upper-and-downward looking image acquisition device. As shown in FIG. 2, FIG. 2 is a top view of a first image-acquisition device according to some embodiments of the present disclosure. The first image-acquisition device 30 may include an upward-looking image acquisition unit 31 and a downward-looking image acquisition unit 32. The upward-looking image acquisition unit 31 and the downward-looking image acquisition unit 32 may be adjacent to each other. A spacing between the upward-looking image acquisition unit 31 and the downward-looking image acquisition unit 32 may be adjusted according to product requirements. The bonding apparatus 100 may be configured to drive, based on the alignment mark of the first element 11 identified by the upward-looking image acquisition unit 31 and the alignment mark of the second element 21 identified by the downward-looking image acquisition unit 32, at least one of the movable pick-up stage 10 or the carrier stage 20 to perform adjustment. In this way, the first element 11 and the second element 21 at the alignment position may be aligned with each other, such that the alignment mark of the first element 11 and the alignment mark of the second element 21 may be aligned in the height direction.

After the first element 11 and the second element 21 at the alignment position are aligned to each other, and before the first element 11 and/or the second element 21 moves along the height direction, the first image-acquisition device 30 may be driven to an initial position. For example, the first image-acquisition device 30 may further include an acquisition device rotation driver 33. The acquisition device rotation driver 33 may be configured to drive the entire first image-acquisition device 30 to rotate, thereby switching the first image-acquisition device 30 between the initial position and a working position. The working position may refer to a position where the first image-acquisition device 30 is located in a bonding position region, so that the alignment marks of both the first element 11 and the second element 21 that are located at the bonding initial position may appear within the field of view of the first image-acquisition device 30. The initial position may refer to a position where the first image-acquisition device 30 is moved out of the bonding position region, so that the first element 11 and the second element 21 may perform bonding.

The upward-looking image acquisition unit 31 may include an upward-looking image processing member 311 and an upward-looking image acquisition member 312. The upward-looking image acquisition unit 31 may have a first viewing angle, which may be an upper viewing angle. The upward-looking image acquisition unit 31 may be configured to identify the alignment mark of the first element 11. The downward-looking image acquisition unit 32 may include a downward-looking image processing member 321 and a downward-looking image acquisition member 322. The downward-looking image acquisition unit 32 may have a second viewing angle, which may be a lower viewing angle. The downward-looking image acquisition unit 32 may be configured to identify the alignment mark of the second element 21. In some embodiments, the upward-looking image acquisition member 312 and the downward-looking image acquisition member 322 may be cameras. For example, the upward-looking image acquisition member 312 may be referred to as an upward-looking camera, and the downward-looking image acquisition member 322 may be referred to as a downward-looking camera.

In some embodiments, both the upward-looking image acquisition unit 31 and the downward-looking image acquisition unit 32 may include an image acquisition component, a prism, and an objective lens system, etc., so as to identify the alignment marks of the first element 11 and the second element 21.

It may be understood that center points of the upward-looking image acquisition unit 31 and the downward-looking image acquisition unit 32 may be a field-of-view center of the upper-and-downward looking image acquisition device. In some embodiments, position information corresponding to the alignment mark of the first element 11 read by the upward-looking image acquisition unit 31 and position information corresponding to the alignment mark of the second element 21 read by the downward-looking image acquisition unit 32 may be converted into position coordinates in a same coordinate system.

In some embodiments, the second image-acquisition device 40 may be disposed beside the bonding position. The second image-acquisition device 40 may have a third viewing angle. The third viewing angle may be used to identify alignment marks of the first element 11 and the second element 21, after the first element 11 and the second element 21 are moved along the height direction and/or after the first element 11 and the second element 21 are bonded. The third viewing angle may be an upper viewing angle or a lower viewing angle. The movable pick-up stage 10 may be configured to drive the first element 11, and/or the carrier stage 20 may be configured to drive the second element 21, to move along the height direction to a bonding position where the first element 11 and the second element 21 complete bonding. The second image-acquisition device 40 may be configured to identify the alignment marks of the first element 11 and the second element 21, after the first element 11 and the second element 21 are moved along the height direction, and/or after the bonding operation of the first element 11 and the second element 21 is performed. That is, after the first element 11 is moved by the movable pick-up stage 10 and/or the second element 21 is moved by the carrier stage 20, along the height direction such that the first element 11 and the second element 21 complete bonding, the alignment marks of the first element 11 and the second element 21 after being moved along the height direction and subjected to the bonding operation may be identified, for obtaining the system-error compensation value.

In some embodiments, as shown in FIG. 1, the second image-acquisition device 40 may be disposed on the second driving member 112 through a suspension arm, so as to follow displacement of the movable pick-up stage 10 that carries the first element 11 in the first direction Y, the second direction X, and the third direction Z. The first direction Y and the second direction X may be different directions that intersect with each other on a horizontal plane. The third direction Z may be a height direction substantially perpendicular to the horizontal plane. Accordingly, position information of the alignment marks of the first element 11 and the second element 21 after bonding may be conveniently and quickly obtained. In this case, the viewing angle of the second image-acquisition device 40 may be a lower viewing angle. The second image-acquisition device 40 may be configured to identify alignment marks of the first element 11 and the second element 21 after downward movement and/or after the bonding operation is performed. In this case, the alignment marks of the first element 11 and the second element 21 after downward movement may be identified, as well as the alignment marks of the first element 11 and the second element 21 after bonding may be identified.

In response to the bonding apparatus 100 performing a system-error correction operation, the second image-acquisition device 40 may be configured to identify the alignment mark of the first element 11 located at a bonding initial position. The bonding apparatus 100 may be configured to drive the movable pick-up stage 10 to move the first element 11, and/or to drive the carrier stage 20 to carry the second element 21, to move along the height direction and perform a bonding operation of the first element 11 and the second element 21. The second image-acquisition device 40 may be configured to identify the alignment mark of the first element 11 after the first element 11 and the second element 21 are bonded with each other. That is, after the first element 11 and the second element 21 are bonded, the second image-acquisition device 40 may identify the alignment mark of the first element 11 and further identify the alignment mark of the second element 21 through the first element 11. It may be understood that, during a downward movement process of the first element 11 and during a bonding process between the first element 11 and the second element 21, a positional deviation of the alignment marks of the first element 11 and the second element 21 after they are bonded, relative to positions of their alignment marks at the bonding initial position, may be caused. In other words, the second image-acquisition device 40 may be configured to identify the alignment marks of the first element 11 and the second element 21 after downward movement and/or after the bonding operation is performed, and to obtain the system-error compensation value. The system-error compensation value may be a displacement compensation value for alignment positions generated during a process in which the movable pick-up stage 10 drives the first element 11 and/or the carrier stage 20 carries the second element 21 to move downward along the height direction to complete bonding between the first element 11 and the second element 21.

In some embodiments, the second image-acquisition device 40 may include at least one image acquisition unit configured to identify the alignment marks of the first element 11 and the second element 21 at the bonding position. For example, the second image-acquisition device 40 may include one image acquisition unit configured to identify the alignment marks of both the first element 11 and the second element 21 after the bonding operation is performed.

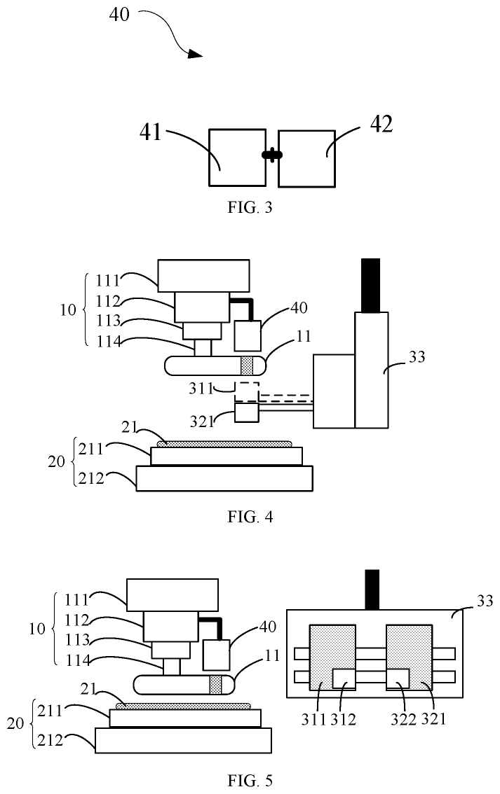

In some embodiments, the second image-acquisition device 40 may include two image acquisition units. As shown in FIG. 3, FIG. 3 is a top view of the second image-acquisition device 40 according to some embodiments of the present disclosure. The second image-acquisition device 40 may be a downward-looking image-acquisition device. The second image-acquisition device 40 may include an image acquisition unit 41 and an image acquisition unit 42. The image acquisition unit 41 and the image acquisition unit 42 may be configured to identify the alignment marks of the first element 11 and the second element 21 at the bonding position, for example, to identify the alignment marks of the first element 11 and the second element 21 after movement along the height direction and/or after the bonding operation is performed. In some embodiments, the second image-acquisition device 40 may be configured to identify alignment marks A1 and A2 of the first element 11 and alignment marks B1 and B2 of the second element 21 corresponding to the first element 11. The alignment mark A1 may correspond to the alignment mark B1, and the alignment mark A2 may correspond to the alignment mark B2. The image acquisition unit 41 may be configured to identify the alignment mark A1 of the first element 11 and the alignment mark B1 of the second element 21. The image acquisition unit 42 may be configured to identify the alignment mark A2 of the first element 11 and the alignment mark B2 of the second element 21. By means of the two image acquisition units, a sufficiently large field of view may be ensured so as to achieve accurate identification of the alignment marks. Those skilled in the art may understand that, the downward-looking image-acquisition device may include three or more downward-looking image acquisition units to ensure a sufficient field of view for accurately identifying the alignment marks. In some embodiments, the downward-looking image acquisition unit 41 and the downward-looking image acquisition unit 42 may include cameras configured to identify the alignment marks of the first element 11 and the second element 21 after movement along the height direction and/or after the bonding operation is performed.

In some embodiments, in response to the bonding apparatus 100 performing a system-error correction operation, the first element 11 may be configured as a first calibration sheet, and the second element 21 may be configured as a second calibration sheet that is matched to the first calibration sheet. That is, the first calibration sheet and the second calibration sheet may be matched to each other and may have at least one pair of corresponding alignment marks thereon. For example, alignment marks A1 and A2 of the first calibration sheet may correspond to alignment marks B1 and B2 of the matched second calibration sheet. The alignment mark A1 may correspond to the alignment mark B1, and the alignment mark A2 may correspond to the alignment mark B2. In a case where the alignment mark A1 is aligned with the alignment mark B1 and the alignment mark A2 is aligned with the alignment mark B2, it may be determined that the first calibration sheet and the second calibration sheet are aligned. In response to the bonding apparatus 100 performing a bonding operation, the first element 11 may be configured as a chip or a wafer to be bonded, and correspondingly, the second element 21 may be configured as a wafer or a chip to be bonded. In this case, the bonding apparatus 100 may be configured to move the movable pick-up stage 10 and/or the carrier stage 20 along the height direction based on the system-error compensation value, such that the chip or wafer to be bonded and the wafer or chip to be bonded after movement along the height direction may be aligned, thereby moving the first element 11 to be bonded to a predetermined surface position of the second element 21 to be bonded and bonding the first element 11 at the predetermined surface position of the second element 21 to be bonded.

It may be understood that the system-error correction operation may refer to a process of obtaining a coordinate deviation value generated in a vertical direction as the system-error compensation value by reading alignment marks of the first element 11 and the second element 21 moved along the height direction to the bonding position. In this case, the first element 11 may be configured as the first calibration sheet and the second element 21 may be configured as the matched second calibration sheet. The system-error compensation operation may refer to a process in which the bonding apparatus 100 adjusts the movable pick-up stage 10 and/or the carrier stage 20 based on the system-error compensation value to perform bonding of the first element 11 and the second element 21. In this case, the first element 11 may be configured as a chip or a wafer to be bonded, and the second element 21 may be configured as a wafer or a chip to be bonded.

Further, in some embodiments, the first calibration sheet may be a transparent calibration sheet, a semi-transparent calibration sheet, or a calibration sheet having a through hole. In this case, the second image-acquisition device 40 may be configured to identify the alignment mark of the second calibration sheet through the first calibration sheet. For example, the transparent calibration sheet may be a glass sheet, and the semi-transparent calibration sheet may be a semi-transparent glass sheet. In response to the bonding apparatus 100 performing the system-error correction operation, the movable pick-up stage 10 may be configured to drive the first calibration sheet and/or the carrier stage may be configured to drive the second calibration sheet to move along the height direction, until the first calibration sheet and the second calibration sheet contact and are bonded with each other. The second image-acquisition device 40 may be configured to identify alignment marks of the first calibration sheet and the second calibration sheet after movement along the height direction and/or after the bonding operation is performed, thereby obtaining the system-error compensation value.

In some embodiments, in response to the first image-acquisition device 30 being driven to the alignment position, as shown in FIG. 4, which is a schematic state view at the alignment position according to some embodiments of the present disclosure, the upward-looking image acquisition unit 31 may be configured to identify the alignment mark of the first element 11. That is, the alignment mark of the first element 11 located at the bonding initial position may be identified by the upward-looking image processing member 311. The downward-looking image acquisition unit 32, in response to the first image-acquisition device 30 being driven to the alignment position, may be configured to identify the alignment mark of the second element 21. That is, the alignment mark of the second element 21 located at the bonding initial position may be identified by the downward-looking image processing member 321.

The bonding apparatus 100 may be configured to drive at least one of the movable pick-up stage 10 or the carrier stage 20 to perform adjustment based on the alignment mark of the first element 11 identified by the upward-looking image acquisition unit 31 and the alignment mark of the second element 21 identified by the downward-looking image acquisition unit 32, so as to align the first element 11 and the second element 21. That is, both the first element 11 and the second element 21 may appear within a camera field of view of the first image-acquisition device 30. A difference calculation may be performed according to coordinate data of the alignment marks of the first element 11 and the second element 21 to obtain differences in X/Y/θ. An adjustment compensation may be performed by driving at least one of the movable pick-up stage 10 or the carrier stage 20, so as to align the first element 11 and the second element 21.

Further, in some embodiments, after aligning the first element 11 and the second element 21, for example, after aligning the first element 11 and the second element 21 in response to the bonding apparatus 100 performing the system-error correction operation/the bonding operation, the movable pick-up stage 10 may be configured to drive the first element 11 and/or the carrier stage may be configured to carry the second element 21 to move along the height direction to a bonding position where the first element 11 and the second element 21 complete bonding. Before the movable pick-up stage 10 drives the first element 11 to move along the height direction, the first image-acquisition device 30 may be driven to a non-alignment position, for example, an initial position of the first image-acquisition device 30. As shown in FIG. 5, which is a schematic state view at a non-alignment position according to some embodiments of the present disclosure, the first image-acquisition device 30 may thus not form an obstruction during movement of the first element 11 and/or the second element 21 along the height direction. In this way, the first element 11 and/or the second element 21 may be moved along the height direction to a predetermined surface position where a surface of the first element 11 and a surface of the second element 21 are in contact with each other. A bonding processing may be performed at the predetermined surface position.

In some embodiments, the second image-acquisition device 40 may be a downward-looking image-acquisition device disposed on the movable pick-up stage 10. In a case where the bonding apparatus 100 performs the system-error correction operation, the first element and the second element aligned at the alignment position may be configured to move along the height direction to the bonding position. The second image-acquisition device 40 may be configured to identify the alignment marks of the first element 11 and the second element 21 at the bonding position. For example, the second image-acquisition device 40 may be configured to identify the alignment marks of the first element 11 and the second element 21 moved along the height direction, and obtain a difference between the alignment mark of the first element and the alignment mark of the second element. The difference between the alignment marks may include a difference in an X direction and a difference in a Y direction in a coordinate system established by the second image-acquisition device 40. For example, the first element 11 may be a transparent first calibration sheet, and the second element 21 may be a second calibration sheet matched to the first element 11. After the movable pick-up stage 10 drives the first element 11 and/or the carrier stage carries the second element 21, to move along the height direction to the bonding position where the first element 11 and the second element 21 complete bonding, the alignment mark of the first calibration sheet may be identified by the second image-acquisition device 40. The alignment mark of the second calibration sheet may be identified through the first calibration sheet. Accordingly, based on the difference between the alignment mark of the first element 11 and the alignment mark of the second element 21 after movement along the height direction and bonding processing, i.e., based on a coordinate difference between the alignment mark of the first element 11 and the alignment mark of the second element 21 in X/Y directions after movement along the height direction and/or after the bonding operation is performed, a system-error value may be obtained, thereby performing the system-error correction operation.

In some embodiments, the bonding apparatus 100 may be configured to perform the system-error correction operation for multiple times to obtain a plurality of system-error values. That is, by repeatedly moving the first element 11 located at the bonding initial position by the movable pick-up stage 10 and/or by repeatedly moving the second element 21 located at the bonding initial position by the carrier stage 20, along the height direction to the bonding position where the first element 11 and the second element 21 complete bonding, the second image-acquisition device 40 may complete identification of the alignment marks of the first element 11 and the second element 21 moved along the height direction. A plurality of system-error values may be obtained through difference calculation. A system-error compensation value may be obtained based on an average of the plurality of system-error values. Before performing the bonding operation, the bonding apparatus 100 may set a movement path of the movable pick-up stage 10 and/or the carrier stage 20 based on the system-error compensation value, and then perform the bonding operation, so that the finally bonded first element 11 and second element 21 may achieve higher-precision alignment.

In some embodiments, the second image-acquisition device 40 may be detachably disposed on the movable pick-up stage 10 to perform the system-error correction operation. It may be understood that, by disposing the second image-acquisition device 40 on the movable pick-up stage 10 to perform the system-error correction operation, after the system-error compensation value is obtained, the second image-acquisition device 40 may be detached. In response to the bonding apparatus 100 performing the bonding operation, the bonding apparatus 100 may be configured to move the movable pick-up stage 10 and/or the carrier stage 20 along the height direction based on the system-error compensation value, so that the first element 11 and the second element 21 after movement along the height direction may be aligned and bonded.

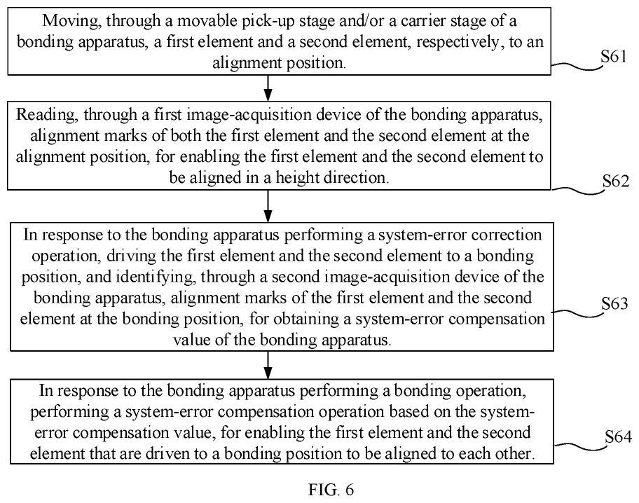

As shown in FIG. 6, FIG. 6 is a flowchart of a bonding method according to some embodiments of the present disclosure. The method may be applied to the bonding apparatus 100 described above. As shown in FIG. 6, the method may include the following operations.

At operation S61, a first element and a second element may be respectively moved to an alignment position through a movable pick-up stage and/or a carrier stage of a bonding apparatus.

The movable pick-up stage 10 and/or the carrier stage 20 of the bonding apparatus 100 may be configured to move the first element 11 and the second element 21 to the alignment position, respectively. The alignment position may include an initial position of the first element 11 and the second element 21 for bonding. The alignment position may further include a position at which the first element 11 and the second element 21 appear within a field of view of the first image-acquisition device 30 of the bonding apparatus 100.

At operation S62, alignment marks of the first element and the second element at the alignment position may be read through a first image-acquisition device of the bonding apparatus, for enabling the first element and the second element to be aligned in a height direction.

The first image-acquisition device 30 of the bonding apparatus 100 may be configured to read the alignment marks of the first element 11 and the second element 21 at the alignment position. Based on the alignment marks, the movable pick-up stage 10 and/or the carrier stage 20 may be driven to perform adjustment, so that the first element 11 and the second element 21 may be aligned to each other. That is, the alignment marks of the first element 11 and the second element 21 may be aligned in a vertical direction.

At operation S63, in response to the bonding apparatus performing a system-error correction operation, the first element and the second element may be driven to a bonding position, and alignment marks of the first element and the second element at the bonding position may be identified through a second image-acquisition device of the bonding apparatus, for obtaining a system-error compensation value of the bonding apparatus.

In response to the bonding apparatus 100 performing the system-error correction operation, the first element 11 and the second element 21 may be driven to the bonding position. For example, the movable pick-up stage 10 and/or the carrier stage 20 may be configured to drive the first element 11 and/or the second element 21 to move along the height direction to complete bonding. The second image-acquisition device 40 of the bonding apparatus 100 may then be configured to identify the alignment marks of the first element 11 and the second element 21 after movement along the height direction and/or after the bonding operation is performed. That is, the alignment marks of the first element 11 and the second element 21 may be identified before movement along the height direction. The alignment marks of the first element 11 and the second element 21 after movement along the height direction and/or after the bonding operation is performed may be further identified. Based on positional changes of the alignment marks of the first element 11 and the second element 21, the system-error correction operation may be performed. By performing the system-error correction operation for multiple times, a plurality of system-error values of the bonding apparatus 100 may be obtained. A system-error compensation value of the bonding apparatus 100 may be obtained based on an average of the plurality of system-error values.

At operation S64, in response to the bonding apparatus performing a bonding operation, a system-error compensation operation may be performed based on the system-error compensation value, for enabling a first element and a second element that are driven to a bonding position to be aligned to each other.

In a case where the bonding apparatus 100 performs the bonding operation, the system-error compensation operation may be performed based on the obtained system-error compensation value, such that the first element 11 and the second element 21 driven to the bonding position may be aligned. That is, the bonding apparatus 100 may be configured to set, based on the system-error compensation value, a compensation value during a process in which the movable pick-up stage 10 and/or the carrier stage 20 moves along the height direction to complete bonding. In this way, the first element 11 to be bonded may be successfully moved along the height direction to a predetermined surface position of the second element 21 to be bonded. The first element 11 may be bonded at the predetermined surface position of the second element 21.

In some embodiments, in response to the bonding apparatus 100 performing the system-error correction operation, the first element 11 may be configured as a first calibration sheet, and the second element 21 may be configured as a second calibration sheet matched to the first calibration sheet. That is, the first calibration sheet and the second calibration sheet may be matched and may have at least one pair of corresponding alignment marks thereon. For example, alignment marks A1 and A2 of the first calibration sheet may correspond to alignment marks B1 and B2 of the matched second calibration sheet. The alignment mark A1 may correspond to the alignment mark B1, and the alignment mark A2 may correspond to the alignment mark B2. When the alignment mark A1 is aligned with the alignment mark B1 and the alignment mark A2 is aligned with the alignment mark B2, it may be determined that the first calibration sheet and the second calibration sheet are aligned to each other.

Further, in response to the bonding apparatus 100 performing the system-error correction operation, driving the first element 11 and the second element 21 to the bonding position, and identifying alignment marks of the first element 11 and the second element 21 at the bonding position through the second image-acquisition device 40 of the bonding apparatus 100, for obtaining the system-error compensation value of the bonding apparatus 100, may include: moving the first element 11 and the second element 21 to the bonding position through the movable pick-up stage 10 and/or the carrier stage 20; and identifying, through the second image-acquisition device 40, a difference between the alignment marks of the first element 11 and the second element 21 at the bonding position as a system-error value, for obtaining the system-error compensation value.

For example, the first element 11 may be a transparent first calibration sheet, and the second element 21 may be a second calibration sheet matched to the first element 11. After the movable pick-up stage 10 drives or moves the first element 11 and/or the carrier stage 20 carries the second element 21 to move along the height direction to the bonding position where the first element 11 and the second element 21 complete bonding, the second image-acquisition device 40 may be configured to identify the alignment marks of the first calibration sheet and identify the alignment mark of the second calibration sheet through the first calibration sheet. Accordingly, based on the difference between the alignment mark of the first element 11 and the alignment mark of the second element 21 after movement along the height direction and bonding processing, i.e., based on a coordinate difference between the alignment mark of the first element 11 and the alignment mark of the second element 21 in X/Y directions after movement along the height direction and/or after the bonding operation is performed, a system-error value may be obtained, thereby performing the system-error correction operation.

In some embodiments, the bonding apparatus 100 may be configured to perform the system-error correction operation for multiple times to obtain a plurality of system-error values. The bonding apparatus 100 may be configured to obtain the system-error compensation value based on an average of the plurality of system-error values.

By performing the system-error correction operation for multiple times by the bonding apparatus 100 to obtain a plurality of system-error values, i.e., repeatedly moving the first element 11 located at the alignment position by the movable pick-up stage 10 and/or moving the second element 21 located at the alignment position by the carrier stage 20, along the height direction to the bonding position where the first element 11 and the second element 21 complete bonding, the second image-acquisition device 40 may complete identification of the alignment marks of the first element 11 and the second element 21 moved along the height direction. A plurality of system-error values may be obtained through difference calculation. A system-error compensation value may be obtained based on an average of the plurality of system-error values. Before performing the bonding operation, the bonding apparatus 100 may set a movement path of the movable pick-up stage 10 and/or the carrier stage 20 based on the system-error compensation value, and then perform the bonding operation, so that the finally bonded first element 11 and the second element 21 may achieve higher-precision alignment.

In some embodiments, the first calibration sheet may be a transparent calibration sheet, a semi-transparent calibration sheet, or a calibration sheet having a through hole.

The first calibration sheet may be a transparent calibration sheet, a semi-transparent calibration sheet, or a calibration sheet having a through hole. That is, the second image-acquisition device 40 may identify an alignment mark of the second calibration sheet through the first calibration sheet. For example, the transparent calibration sheet may be a glass sheet, and the semi-transparent calibration sheet may be a semi-transparent glass sheet. In response to the bonding apparatus 100 performing the system-error correction operation, the movable pick-up stage 10 may drive the first calibration sheet and/or the carrier stage may drive the second calibration sheet to move along the height direction until the first calibration sheet and the second calibration sheet contact and are bonded. The second image-acquisition device 40 may be configured to identify alignment marks of the first calibration sheet and the second calibration sheet after movement along the height direction and/or after the bonding operation is performed, thereby obtaining the system-error compensation value.

In some embodiments, in response to the bonding apparatus 100 performing the bonding operation, the first element 11 may be configured as a chip or a wafer to be bonded, and the second element 21 may be configured as a wafer or a chip to be bonded.

Further, in response to the bonding apparatus 100 performing the bonding operation, performing the system-error compensation operation based on the system-error compensation value so that the first element 11 and the second element 21 driven to the bonding position may be aligned may include: moving, through the movable pick-up stage 10 and/or the carrier stage 20, the first element 11 and the second element 21 to the bonding position, and performing the system-error compensation operation, so that the first element and the second element driven to the bonding position may be aligned.

The moving, through the movable pick-up stage 10 and/or the carrier stage 20, the first element 11 and the second element 21 to the bonding position, and performing the system-error compensation operation, may include the following operations: adjusting the first element 11 and the second element 21 at the alignment position based on the obtained system-error compensation value of the bonding apparatus 100, and moving the first element 11 and the second element 21 to the bonding position, so that the first element 11 and the second element 21 driven to the bonding position may be aligned for performing the bonding operation.

In some embodiments, the moving, through the movable pick-up stage 10 and/or the carrier stage 20, the first element 11 and the second element 21 to the bonding position, and performing the system-error compensation operation so that the first element 11 and the second element 21 driven to the bonding position may be aligned, may include the following operations: adjusting the movable pick-up stage 10 and/or the carrier stage 20 based on the system-error compensation value to perform the system-error compensation operation on the first element 11 and the second element 21 at the alignment position, and then moving the movable pick-up stage 10 and/or the carrier stage 20 along the height direction so that the first element 11 and the second element 21 may be driven to the bonding position. In some embodiments, the movable pick-up stage 10 and/or the carrier stage 20 may be moved along the height direction to drive the first element 11 and the second element 21 to the bonding position, meanwhile the movable pick-up stage 10 and/or the carrier stage 20 may be adjusted based on the system-error compensation value to perform the system-error compensation operation on the first element 11 and the second element 21.

In some embodiments, before reading, through the first image-acquisition device 30 of the bonding apparatus 100, the alignment marks of the first element 11 and the second element 21 at the alignment position so that the first element 11 and the second element 21 may be aligned in the height direction, the first image-acquisition device 30 may be driven from an initial position to a working position, so as to read the alignment marks of the first element 11 and the second element 21 at the alignment position. The working position may refer to a position where the first image-acquisition device 30 is located in a bonding position region, so that the alignment marks of the first element 11 and the second element 21 located at a bonding initial position may appear within a field of view of the first image-acquisition device 30. The initial position may refer to a position where the first image-acquisition device 30 is moved out of the bonding position region.

Further, after reading, through the first image-acquisition device 30 of the bonding apparatus 100, the alignment marks of the first element 11 and the second element 21 at the alignment position so that the first element 11 and the second element 21 may be aligned in the height direction, the first image-acquisition device 30 may be driven from the working position to the initial position, so as to facilitate subsequent system-error correction operation or bonding operation.

In some embodiments, the first image-acquisition device 30 may be an upper-and-downward looking image acquisition device.

The first image-acquisition device 30 may be configured to obtain the alignment mark of the first element 11 and the alignment mark of the second element 21. For example, the first image-acquisition device 30 may include an upward-looking image acquisition unit and a downward-looking image acquisition unit. The upward-looking image acquisition unit may have a first viewing angle and may be configured to identify the alignment mark of the first element 11. The downward-looking image acquisition unit may have a second viewing angle and may be configured to identify the alignment mark of the second element 21. The upward-looking image acquisition unit and the downward-looking image acquisition unit may be arranged opposite to each other. For example, when identifying the alignment marks, the upward-looking image acquisition unit may be located on a side of the base 51 facing the top plate 521 of the machine frame 52, and the downward-looking image acquisition unit may be located on a side of the top plate 521 of the machine frame 52 facing the base 51. In some embodiments, the upward-looking image acquisition unit and the downward-looking image acquisition unit may be arranged as an integral device, for example, an upper-and-downward looking image acquisition device. In this case, when identifying the alignment marks, the upper-and-downward looking image acquisition device may be located in a cavity formed jointly by the base 51 and the machine frame 52.

The foregoing may merely be some embodiments of the present disclosure and may not be intended to limit the scope of the present disclosure. Any equivalent structures or equivalent process transformations made by using the contents of the description and the accompanying drawings of the present disclosure, or directly or indirectly applied to other related technical fields, may be included within the scope of patent protection of the present disclosure.

What is claimed is:

1. A bonding apparatus having a system-error compensation function, comprising:
a movable pick-up stage, configured to move a first element;
a carrier stage, configured to move a second element;
a first image-acquisition device, configured to read alignment marks of both the first element and the second element that are driven to an alignment position; and
a second image-acquisition device, wherein in response to the bonding apparatus performing a system-error correction operation, the second image-acquisition device is configured to read alignment marks of both the first element and the second element that are driven to a bonding position, for obtaining a system-error compensation value;
wherein in response to the bonding apparatus performing a bonding operation, the bonding apparatus is configured to perform a system-error compensation operation based on the system-error compensation value, for enabling the first element and the second element that are driven to the bonding position to be aligned to each other.

2. The bonding apparatus as claimed in claim 1, wherein the bonding apparatus is further configured to adjust, based on the alignment marks read by the first image-acquisition device, the first element and the second element at the alignment position, for aligning the first element and the second element at the alignment position in a height direction.

3. The bonding apparatus as claimed in claim 1, wherein
in response to the bonding apparatus performing the system-error correction operation, the first element is configured as a first calibration sheet, and the second element is configured as a second calibration sheet matched to the first calibration sheet; and
in response to the bonding apparatus performing the bonding operation, the first element is configured as a chip or a wafer to be bonded, and the second element is configured as a wafer or a chip to be bonded.

4. The bonding apparatus as claimed in claim 3, wherein the first calibration sheet is a transparent calibration sheet, a semi-transparent calibration sheet, or a calibration sheet having a through hole.

5. The bonding apparatus as claimed in claim 2, wherein in response to the bonding apparatus performing the system-error correction operation:
the first element and the second element that are aligned at the alignment position are configured to move along the height direction to the bonding position, and
the second image-acquisition device is configured to identify the alignment marks of both the first element and the second element at the bonding position, and to obtain a difference between the alignment mark of the first element and the alignment mark of the second element as a system-error value, for performing the system-error correction operation.

6. The bonding apparatus as claimed in claim 5, wherein the bonding apparatus is configured to perform the system-error correction operation for multiple times to obtain a plurality of system-error values, and the bonding apparatus is further configured to obtain the system-error compensation value based on an average of the plurality of system-error values.

7. The bonding apparatus as claimed in claim 5, wherein the second image-acquisition device is detachably disposed on the movable pick-up stage to perform the system-error correction operation.

8. The bonding apparatus as claimed in claim 5, wherein the second image-acquisition device comprises at least one image acquisition unit, the at least one image acquisition unit is configured to identify the alignment marks of both the first element and the second element at the bonding position.

9. The bonding apparatus as claimed in claim 5, wherein
in response to the bonding apparatus performing the bonding operation, the bonding apparatus is configured to adjust at least one of the movable pick-up stage or the carrier stage based on the system-error compensation value to perform the system-error compensation operation on the first element and the second element at the alignment position, and then to move at least one of the movable pick-up stage or the carrier stage along the height direction to drive the first element and the second element to the bonding position;
in response to the bonding apparatus performing the bonding operation, the bonding apparatus is configured to move at least one of the movable pick-up stage or the carrier stage along the height direction to drive the first element and the second element to the bonding position, meanwhile to adjust at least one of the movable pick-up stage or the carrier stage based on the system-error compensation value to perform the system-error compensation operation on the first element and the second element.

10. The bonding apparatus as claimed in claim 1, further comprising a base and a machine frame disposed on the base;
wherein the movable pick-up stage is disposed on the machine frame, the carrier stage is disposed on the base, and at least one of the movable pick-up stage or the carrier stage is configured to move along an X direction, a Y direction, and a height direction Z, and to rotate on a vertical plane substantially perpendicular to a horizontal plane to adjust a horizontal state of at least one of the movable pick-up stage or the carrier stage.

11. The bonding apparatus as claimed in claim 1, wherein in a case where the first image-acquisition device is an upper-and-downward looking image acquisition device, the first image-acquisition device comprises:
an upward-looking image acquisition unit, configured to, in response to the first image-acquisition device being driven to a working position, identify the alignment mark of the first element; and
a downward-looking image acquisition unit, configured to, in response to the first image-acquisition device being driven to the working position, identify the alignment mark of the second element;
wherein the bonding apparatus is configured to drive at least one of the movable pick-up stage or the carrier stage to perform adjustment based on the alignment mark of the first element identified by the upward-looking image acquisition unit and the alignment mark of the second element identified by the downward-looking image acquisition unit, for aligning the first element and the second element at the alignment position.

12. The bonding apparatus as claimed in claim 11, wherein after the first element and the second element at the alignment position are aligned to each other and before at least one of the first element or the second element moves along the height direction, the first image-acquisition device is driven to an initial position.

13. A bonding method, applied to a bonding apparatus, and comprising:
moving, through at least one of a movable pick-up stage or a carrier stage of the bonding apparatus, a first element and a second element to an alignment position, respectively;
reading, through a first image-acquisition device of the bonding apparatus, alignment marks of both the first element and the second element that are at the alignment position, for aligning the first element and the second element in a height direction;
in response to the bonding apparatus performing a system-error correction operation, driving the first element and the second element to a bonding position, and identifying, through a second image-acquisition device of the bonding apparatus, alignment marks of both the first element and the second element at the bonding position, for obtaining a system-error compensation value of the bonding apparatus; and
in response to the bonding apparatus performing a bonding operation, performing a system-error compensation operation based on the system-error compensation value, for enabling the first element and the second element that are driven to the bonding position to be aligned to each other.

14. The bonding method as claimed in claim 13, wherein in response to the bonding apparatus performing the system-error correction operation, the first element is configured as a first calibration sheet, and the second element is configured as a second calibration sheet matched to the first calibration sheet; and
wherein the, in response to the bonding apparatus performing the system-error correction operation, driving the first element and the second element to the bonding position and identifying, through the second image-acquisition device of the bonding apparatus, the alignment marks of both the first element and the second element at the bonding position, for obtaining the system-error compensation value of the bonding apparatus, comprises:
moving, through at least one of the movable pick-up stage or the carrier stage, the first element and the second element to the bonding position; and
identifying, through the second image-acquisition device, a difference between the alignment mark of the first element and the alignment mark of the second element at the bonding position as a system-error value, for obtaining the system-error compensation value.

15. The bonding method as claimed in claim 14, wherein the bonding apparatus is configured to perform the system-error correction operation for multiple times to obtain a plurality of system-error values, and the bonding apparatus is further configured to obtain the system-error compensation value based on an average of the plurality of system-error values.

16. The bonding method as claimed in claim 14, wherein the first calibration sheet is a transparent calibration sheet, a semi-transparent calibration sheet, or a calibration sheet having a through hole.

17. The bonding method as claimed in claim 13, wherein in response to the bonding apparatus performing the bonding operation, the first element is configured as a chip or a wafer to be bonded, and the second element is configured as a wafer or a chip to be bonded; and
wherein the, in response to the bonding apparatus performing the bonding operation, performing the system-error compensation operation based on the system-error compensation value, for enabling the first element and the second element that are driven to the bonding position to be aligned to each other, comprises:
moving, through at least one of the movable pick-up stage or the carrier stage, the first element and the second element to the bonding position, and performing the system-error compensation operation, for enabling the first element and the second element that are driven to the bonding position to be aligned to each other.

18. The bonding method as claimed in claim 17, wherein the moving, through at least one of the movable pick-up stage or the carrier stage, the first element and the second element to the bonding position, and performing the system-error compensation operation, for enabling the first element and the second element that are driven to the bonding position to be aligned to each other, comprises:
adjusting at least one of the movable pick-up stage or the carrier stage based on the system-error compensation value to perform the system-error compensation operation on the first element and the second element at the alignment position, and then moving at least one of the movable pick-up stage or the carrier stage along the height direction to drive the first element and the second element to the bonding position; or
moving at least one of the movable pick-up stage or the carrier stage along the height direction to drive the first element and the second element to the bonding position, and meanwhile adjusting at least one of the movable pick-up stage or the carrier stage based on the system-error compensation value to perform the system-error compensation operation on the first element and the second element.

19. The bonding method as claimed in claim 13, wherein
before the reading, through the first image-acquisition device of the bonding apparatus, the alignment marks of both the first element and the second element that are at the alignment position, for aligning the first element and the second element in the height direction, the method further comprises:
driving the first image-acquisition device from an initial position to a working position, for reading the alignment marks of both the first element and the second element at the alignment position; and
after the reading, through the first image-acquisition device of the bonding apparatus, the alignment marks of both the first element and the second element that are at the alignment position, for aligning the first element and the second element in the height direction, the method further comprises:
driving the first image-acquisition device from the working position to the initial position, for facilitating the system-error correction operation or the bonding operation subsequently.

20. The bonding method as claimed in claim 19, wherein the first image-acquisition device is an upper-and-downward looking image acquisition device.
